(19) United States
(12) Patent Application Publication
(10) Pub. No.: US 2021/0057585 A1
(43) Pub. Date: Feb. 25, 2021

(54) THIN FILM TRANSISTOR, MANUFACTURING METHOD THEREOF, AND DISPLAY DEVICE

(71) Applicant: SHENZHEN ROYOLE TECHNOLOGIES CO., LTD., Shenzhen (CN)

(72) Inventors: Guowen Yan, Shenzhen (CN); Can Zou, Shenzhen (CN); Wei Cheng Kao, Shenzhen (CN)

(21) Appl. No.: 17/092,595

(22) Filed: Nov. 9, 2020

Related U.S. Application Data
(63) Continuation of application No. PCT/CN2018/086126, filed on May 9, 2018.

(51) Int. Cl. H01L 29/786

(52) U.S. Cl. CPC H01L 29/78693; H01L 29/78696

(57) ABSTRACT

A thin film transistor, a manufacturing method for the thin film transistor, and a display device are provided. The thin film transistor includes a substrate, and further includes an oxide semiconductor layer, a gate electrode, a gate insulation layer, a source electrode, and a drain electrode that are disposed on the substrate. The oxide semiconductor layer includes a channel portion, a first contact portion, and a second contact portion, where the source electrode is in contact with the first contact portion, and the drain electrode is in contact with the second contact portion. The channel portion at least partially protrudes in a direction away from the substrate, and the gate insulation layer and the gate electrode are successively stacked on the channel portion.

### CROSS-REFERENCE TO RELATED APPLICATION(S)

This application is a continuation of International application No. PCT/CN2018/086126, filed on May 9, 2018, the entire disclosure of which is hereby incorporated by reference in its entirety.

### TECHNICAL FIELD

This disclosure relates to the technical field of display, and particularly to a thin film transistor, a manufacturing method thereof, and a display device.

### BACKGROUND

In recent years, as materials used in oxide semiconductor layers of transistors, oxide semiconductors have attracted much attention. For example, transistors using amorphous oxide semiconductors containing indium, gallium, and zinc have been widely used.

However, in the transistor, there may be a small amount of carriers (e.g. about 1 micron (1 μm)) which may diffuse from a conductive region to a semiconductor region. To this end, it is necessary to reserve enough length for the channel of the amorphous oxide transistor, which affects the improvement of resolution.

### SUMMARY

In view of the above, implementations of the disclosure provide a thin film transistor, a manufacturing method thereof, an array substrate, and a display device.

A thin film transistor is provided. The thin film transistor includes a substrate, an oxide semiconductor layer, a gate electrode, a gate insulation layer, a source electrode, and a drain electrode, where the oxide semiconductor layer, the gate electrode, the gate insulation layer, the source electrode, and the drain electrode are disposed on the substrate. The oxide semiconductor layer includes a channel portion, a first contact portion, and a second contact portion, where the source electrode is in contact with the first contact portion, and the drain electrode is in contact with the second contact portion. The channel portion at least partially protrudes in a direction away from the substrate, and the gate insulation layer and the gate electrode are successively stacked on the channel portion.

In at least one implementation, the channel portion includes a first part and two second parts respectively located on two opposite ends of the first part. Each of the two second parts is bent from one of the two opposite ends of the first part toward the substrate.

In at least one implementation, the first part is parallel to the substrate, and an angle defined between each of the two second parts and the first part is larger than 90 degrees and smaller than 180 degrees.

In at least one implementation, the channel portion further includes two third parts, one third part is connected between one second part and the first contact portion, and the other third part is connected between the other second part and the second contact portion.

In at least one implementation, the two third parts are both parallel to the first part.

In at least one implementation, the gate insulation layer covers the first part, the two second parts, and the two third parts.

In at least one implementation, the first part and the two second parts jointly form a protrusion relative to the substrate.

In at least one implementation, the thin film transistor further includes a buffer layer, where the buffer layer is located on and at least partially protrudes relative to the substrate, and the oxide semiconductor layer is arranged on the buffer layer.

In at least one implementation, the buffer layer includes a first buffer layer and a second buffer layer covering the first buffer layer, and the oxide semiconductor layer is arranged on a surface of the second buffer layer away from the first buffer layer.

In at least one implementation, the first buffer layer has a first end adjacent to the substrate, and the first end has a width greater than a second end opposite to the first end.

In at least one implementation, the first buffer layer and the second buffer layer are made from a same material, and the second buffer layer and the first buffer layer are arranged on the substrate in layers.

In one example, the first buffer layer can be made from at least one material of silicon oxide or silicon nitride.

In at least one implementation, an orthographic projection of the first contact portion on the substrate has no overlap with an orthographic projection of the first buffer layer on the substrate.

In at least one implementation, an orthographic projection of the second contact portion on the substrate has no overlap with an orthographic projection of the first buffer layer on the substrate.

In at least one implementation, the oxide semiconductor layer is made from materials including indium gallium zinc oxide.

An array substrate including the thin film transistor described above.

A display device including the array substrate described above.

A manufacturing method for the thin film transistor is provided. The manufacturing method includes the following. An oxide semiconductor layer is formed on a substrate, where a part of the oxide semiconductor layer forms a protrusion in a direction away from the substrate. A gate insulation layer and a gate electrode are formed on the oxide semiconductor layer successively. A conductive treatment is performed on two opposite ends of the oxide semiconductor layer to form a first contact portion and a second contact portion, where the oxide semiconductor layer connected between the first contact portion and the second contact portion forms a channel portion, and the channel portion at least partially protrudes in a direction away from the substrate. A source electrode and a drain electrode are formed on the oxide semiconductor layer, where the source electrode is in contact with the first contact portion and the drain electrode is in contact with the second contact portion.

In at least one implementation, prior to forming the oxide semiconductor layer on the substrate, the following can be conducted. A buffer layer is formed on the substrate, where the buffer layer at least partially protrudes in a direction away from the substrate.

In at least one implementation, the oxide semiconductor layer is formed on the substrate as follows. The oxide semiconductor layer is formed on the buffer layer, where a part of the oxide semiconductor layer corresponding to a protrusion of the buffer layer forms a protrusion.

In at least one implementation, the buffer layer is formed on the substrate as follows. A protruded first buffer layer is formed on the substrate. A second buffer layer is formed on the protruded first buffer layer and the substrate, where at least a part of the channel portion, the second buffer layer, and the protruded first buffer layer are stacked together.

In at least one implementation, the oxide semiconductor layer is formed on the substrate as follows. The oxide semiconductor layer is formed on a surface of the second buffer layer away from the protruded first buffer layer.

In at least one implementation, the source electrode and the drain electrode are formed on the oxide semiconductor layer as follows. A planarization layer is formed on the oxide semiconductor layer and the gate electrode, and the source electrode and the drain electrode are formed on the planarization layer.

According to the thin film transistor, the manufacturing method for the thin film transistor, the array substrate, and the display device that are provided herein, since the channel portion of the oxide semiconductor layer protrudes toward the gate electrode to form a curved structure, the length of the channel portion is long enough. In other words, by means of that the channel portion is designed to extend vertically, the length of the thin film transistor in the horizontal direction can be reduced, such that the resolution can be improved.

### BRIEF DESCRIPTION OF THE DRAWINGS

To describe technical solutions in implementations of the disclosure more clearly, the following briefly introduces accompanying drawings required for illustrating the implementations. Apparently, the accompanying drawings in the following description illustrate some implementations. Those of ordinary skill in the art may also obtain other drawings based on these accompanying drawings without creative efforts.

FIG. 1 is a cross-sectional view of a thin film transistor according to implementations of the disclosure.

FIG. 2 is a flow chart illustrating a manufacturing method for the thin film transistor according to implementations of the disclosure.

FIG. 3 is a cross-sectional view of a structure formed in an operation at block 201 illustrated in FIG. 2.

FIG. 4 is a cross-sectional view of a structure formed in an operation at block 202 illustrated in FIG. 2.

FIG. 5 is a cross-sectional view of a structure formed in an operation at block 203 illustrated in FIG. 2.

FIG. 6 is a cross-sectional view of a structure formed in an operation at block 204 illustrated in FIG. 2.

FIG. 7 is a cross-sectional view of a structure formed in an operation at block 205 illustrated in FIG. 2.

FIG. 8 is a flow chart illustrating an operation at block 201 in the manufacturing method for the thin film transistor illustrated in FIG. 2.

FIG. 9 is a cross-sectional view of a structure formed in an operation at block 2011 illustrated in FIG. 8.

FIG. 10 is a schematic view of an array substrate according to implementations of the disclosure.

FIG. 11 is a schematic view of a display device according to implementations of the disclosure.

### DETAILED DESCRIPTION

Hereinafter, technical solutions embodied in implementations of the disclosure will be described in a clear and comprehensive manner in conjunction with the accompanying drawings. It is obvious that implementations described herein are merely some rather than all of the implementations of the disclosure. All other implementations obtained by those of ordinary skill in the art based on the implementations of the disclosure without creative efforts shall fall within the protection scope of the disclosure.

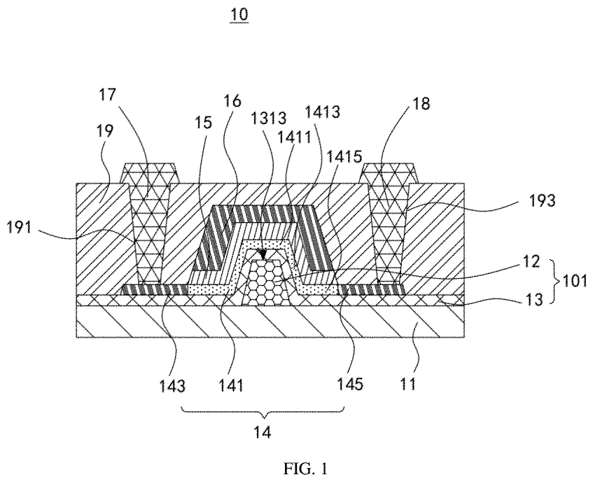

As illustrated in FIG. 1, a thin film transistor 10 is provided in implementation of the disclosure. The thin film transistor 10 includes a substrate 11, and further includes an oxide semiconductor layer 14, a gate insulation layer 15, a gate electrode (“gate” for short) 16, a source electrode (“source” for short) 17, and a drain electrode (“drain” for short) 18 that are disposed on the substrate 11. The oxide semiconductor layer 14 includes a channel portion 141, a first contact portion 143, and a second contact portion 145. The channel portion 141 is connected between the first contact portion 143 and the second contact portion 145. The source electrode 17 is in contact with the first contact portion 143, and the drain electrode 18 is in contact with the second contact portion 145. The channel portion 141 at least partially protrudes toward the gate electrode 16. The gate insulation layer 15 and the gate electrode 16 are successively stacked on the channel portion 141.

Since the channel portion 141 at least partially protrudes toward the gate electrode 16 to form a curved structure, the overall length of the channel portion 141 is increased without increasing a length of the thin film transistor 10 in a horizontal direction. In other words, the length of the channel portion 141 is increased while an effective area occupied by the thin film transistor 10 in the horizontal direction is reduced, which is beneficial to improving pixels per inch (PPI) of a display device.

The channel portion 141 includes a first part 1411 and two second parts 1413 respectively located on two opposite ends of the first part 1411. Each of the two second parts 1413 is bent from one of the two opposite ends of the first part 1411 toward the substrate 11. The first part 1411 and the two second parts 1413 jointly form a protrusion relative to the substrate 11. The channel portion 141 further includes two third parts 1415. One third part 1415 is connected between one second part 1413 and the first contact portion 143, and the other third part 1415 is connected between the other second part 1413 and the second contact portion 145. According to implementations, the first part 1411 is substantially parallel to the substrate 11. An angle between each of the two second parts 1413 and the first part 1411 is larger than 90 degrees and smaller than 180 degrees. The two third parts 1415 are both parallel to the first part 1411.

In one example, the substrate 11 is a glass substrate. It can be understood that the substrate 11 can be made from other materials, such as Polyimide (PI).

In one example, the oxide semiconductor layer 14 is made from metal oxide semiconductor. For example, the metal oxide includes indium gallium zinc oxide (IGZO), hafnium indium zinc oxide (HIZO), indium zinc oxide (IZO), amorphous indium zinc oxide (a-InZnO), amorphous zinc oxide doped fluoride oxide (ZnO:F), indium oxide doped tin oxide (In2O3:Sn), amorphous indium oxide doped molybdenum oxide (In2O3:Mo), chromium tin oxide (Cr2SnO4), amorphous zinc oxide doped aluminum oxide (ZnO:Al), amorphous titanium oxide doped niobium oxide (TiO2:Nb), or other metal oxides. In the implementation, the metal oxide is IGZO.

The thin film transistor 10 further includes a buffer layer 101. The buffer layer 101 is located on and at least partially protrudes relative to the substrate 11. The oxide semiconductor layer 14 is arranged on the buffer layer 101. In an implementation, the buffer layer 101 includes a first buffer layer 12 and a second buffer layer 13. The first buffer layer 12 protrudes relative to the substrate 11. The second buffer layer 13 covers the first buffer layer 12. The oxide semiconductor layer 14 is arranged on a surface of the second buffer layer 13 away from the first buffer layer 12. It can be understood that in another implementation, the thin film transistor 10 merely includes the first buffer layer 12 or the second buffer layer 13, as long as the channel portion 141 in contact with the first buffer layer 12 or the second buffer layer 13 is bent and has a protruded shape.

In one example, the second buffer layer 13 protrudes in a direction away from the substrate 11 and defines a receiving groove 1313 on a side of the second buffer layer 13 adjacent to the substrate 11. The first buffer layer 12 protrudes relative to the substrate 11 and is received in the receiving groove 1313. In other words, the first part 1411 of the channel portion 141, the second buffer layer 13, and the first buffer layer 12 are stacked together.

In at least one implementation, the first buffer layer 12 and the second buffer layer 13 are made from a same material. During manufacturing the thin film transistor 10, the first buffer layer 12 and the second buffer layer 13 are successively formed on the substrate 11 (i.e., the first buffer layer 12 and the second buffer layer 13 are arranged in layers). That is, the first buffer layer 12 is formed on the substrate 11, and then the second buffer layer 13 is formed on the substrate 11 and the first buffer layer 12, so as to reduce the difficulty of the manufacturing. It can be understood that the buffer layer 101 can be arranged on the whole substrate 11 or a local region of the substrate 11.

The first buffer layer 12 has a first end adjacent to the substrate 11 and a second end opposite to the first end, and the first end has a width greater than the second end. The first buffer layer 12 is substantially trapezoidal. There is no restriction on the shape of the first buffer layer 12. The first buffer layer 12 can be square, triangular, circular, or the like.

It can be understood that the first buffer layer 12 can be made from at least one material of silicon oxide or silicon nitride. The second buffer layer 13 can be made from at least one material of silicon oxide or silicon nitride.

In at least one implementation, an orthographic projection of the first contact portion 143 on the substrate 11 has no overlap with an orthographic projection of the first buffer layer 12 on the substrate 11. An orthographic projection of the second contact portion 145 on the substrate 11 has no overlap with an orthographic projection of the first buffer layer 12 on the substrate 11. In other words, the first contact portion 143 is not overlapped with the first buffer layer 12, and the second contact portion 145 is not overlapped with the first buffer layer 12.

In addition to the horizontal direction, the channel portion 141 can also extend in the vertical direction to increase the overall length of the channel portion 141, thereby reserving enough length for carrier diffusion. Moreover, due to the short length of the thin film transistor in the horizontal direction, a resolution of a display panel with thin film transistors can be improved.

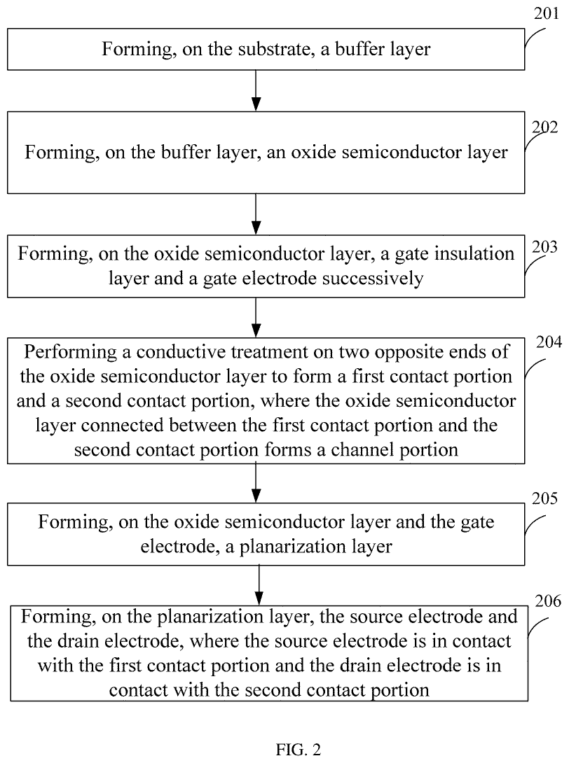

Implementations of the disclosure further provide a manufacturing method for the thin film transistor. As illustrated in FIG. 2, the manufacturing method begins at block 201.

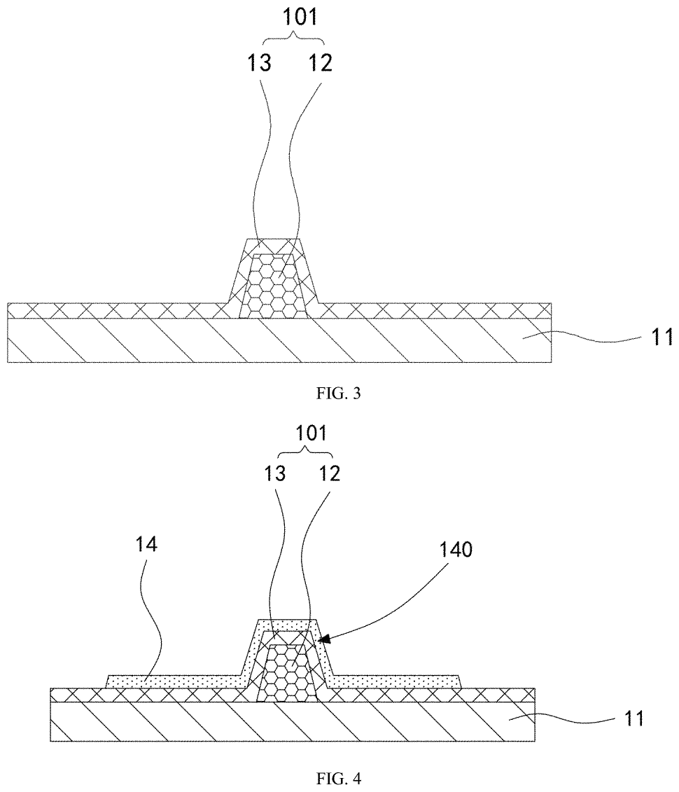

At block 201, a buffer layer 101 is formed on a substrate 11, where the buffer layer 101 partially protrudes relative to the substrate 11 (as illustrated in FIG. 3).

At block 202, an oxide semiconductor layer 14 is formed on the buffer layer 101, where a part of the oxide semiconductor layer 14 corresponding to a protrusion of the buffer layer 101 forms a protrusion 140 (as illustrated in FIG. 4).

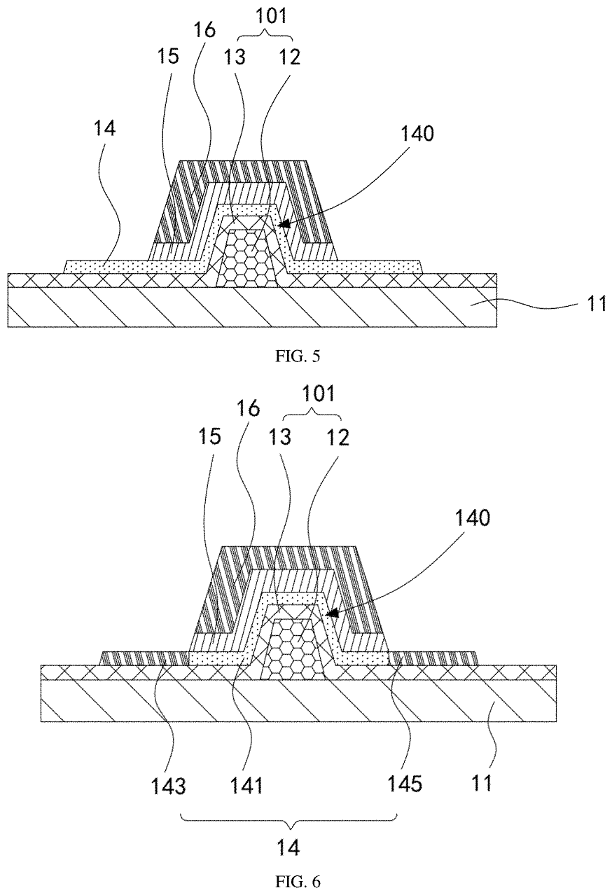

At block 203, a gate insulation layer 15 and a gate electrode 16 are successively formed on the oxide semiconductor layer 14 (as illustrated in FIG. 5).

At block 204, a conductive treatment is performed on two opposite ends of the oxide semiconductor layer 14 to form a first contact portion 143 and a second contact portion 145, where the oxide semiconductor layer connected between the first contact portion 143 and the second contact portion 145 forms a channel portion 141, and the channel portion 141 is at least partially formed by the protrusion 140 (as illustrated in FIG. 6).

In other words, the channel portion 141 is at least partially located on the protrusion of the buffer layer 101, and the channel portion 141 and the buffer layer 101 are stacked together.

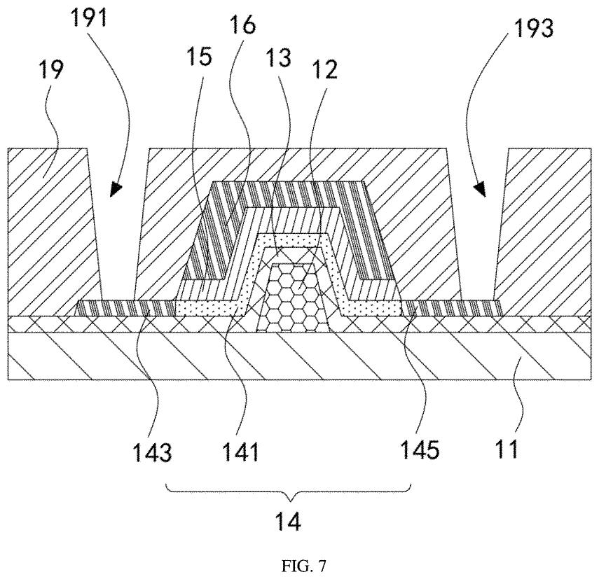

At block 205, a planarization layer 19 is formed on the oxide semiconductor layer 14 and the gate electrode 16 (as illustrated in FIG. 7).

At block 206, referring back to FIG. 1, the source electrode 17 and the drain electrode 18 are formed on the planarization layer 19, where the source electrode 17 is in contact with the first contact portion 143 and the drain electrode 18 is in contact with the second contact portion 145.

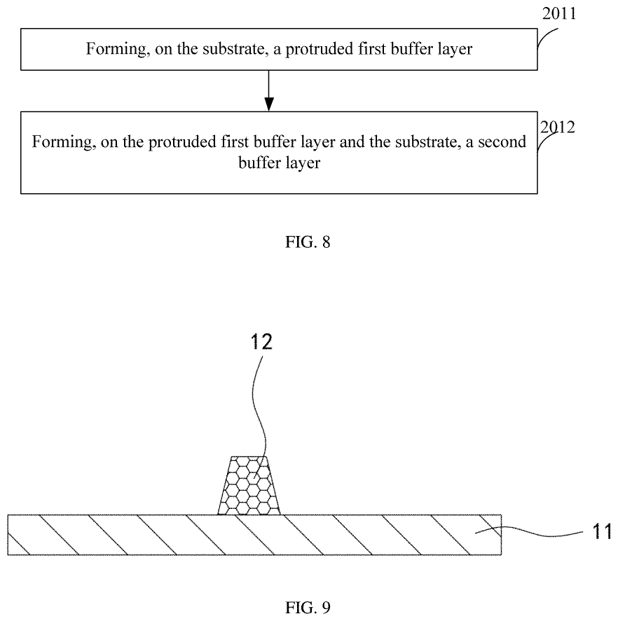

As illustrated in FIG. 8, the operation at block 201 includes operations at block 2011 and block 2012.

At block 2011, a protruded first buffer layer 12 is formed on the substrate 11 (as illustrated in FIG. 9).

In one example, the operation at block 2011 includes the following. A pre-fabricated film layer is formed on the substrate 11, and the pre-fabricated film layer is exposed and etched to form the patterned first buffer layer 12.

At block 2012, a second buffer layer 13 is formed on the first buffer layer 12 and the substrate 11.

In operation at block 202, the oxide semiconductor layer is formed on the buffer layer as follows. The oxide semiconductor layer 14 is formed on a surface of the second buffer layer 13 away from the first buffer layer 12. According to implementations, the second buffer layer 13 is formed on the first buffer layer 12 and the substrate 11 by a chemical vapor deposition method.

At block 204, performing a conductive treatment on the two opposite ends of the oxide semiconductor layer further includes the following. The first part 1411 of the channel portion 141, the second buffer layer 13, and the first buffer layer 12 are stacked together.

The operation at block 203 includes the following, i.e., the gate insulation layer and the gate electrode are successively formed on the oxide semiconductor layer as follows. A pre-fabricated gate insulation layer is formed on the oxide semiconductor layer 14 by a chemical vapor deposition method. A pre-fabricated gate electrode layer is deposited on the pre-fabricated gate insulation layer by a physical vapor deposition method. The pre-fabricated gate insulation layer and the pre-fabricated gate electrode layer are exposed and etched to form the patterned gate insulation layer 15 and the patterned gate electrode 16.

The operation at block 205 includes the following, i.e., the planarization layer is formed on the oxide semiconductor layer and the gate electrode as follows. A pre-fabricated planarization layer is formed on the oxide semiconductor layer and the gate electrode. The pre-fabricated planarization layer is exposed and etched to form the patterned planarization layer 19. The planarization layer 19 defines a first through hole 191 and a second through hole 193. The source electrode 17 is in contact with the first contact portion 143 via the first through hole 191, and the drain electrode 18 is in contact with the second contact portion 145 via the second through hole 193.

It can be understood that the operation at block 201 may not be performed, that is, the oxide semiconductor layer is directly formed on the substrate, and a part of the oxide semiconductor layer directly forms a protrusion relative to the substrate. In addition, the operation at block 205 may not be performed. That is, in the operation at block 206, the source electrode and the drain electrode are formed on the oxide semiconductor layer. The manufacturing method for a thin film transistor includes the following.

An oxide semiconductor layer is formed on a substrate, where a part of the oxide semiconductor layer forms a protrusion in a direction away from the substrate. A gate insulation layer and a gate electrode are successively formed on the oxide semiconductor layer. A conductive treatment is performed on two opposite ends of the oxide semiconductor layer to form a first contact portion and a second contact portion. The oxide semiconductor layer connected between the first contact portion and the second contact portion forms a channel portion, and the channel portion at least partially protrudes in a direction away from the substrate. A source electrode and a drain electrode are formed on the oxide semiconductor layer, where the source electrode is in contact with the first contact portion and the drain electrode is in contact with the second contact portion.

It can be understood that the oxide semiconductor layer is formed on the buffer layer or the substrate as follows. A pre-fabricated oxide semiconductor layer is formed by a physical vapor deposition method, and the pre-fabricated oxide semiconductor layer is exposed and etched to form the patterned oxide semiconductor layer.

It can be understood that the source electrode and the drain electrode are formed on the oxide semiconductor layer as follows. A planarization layer is formed on the oxide semiconductor layer and the gate electrode, and the source electrode and the drain electrode are formed on the planarization layer.

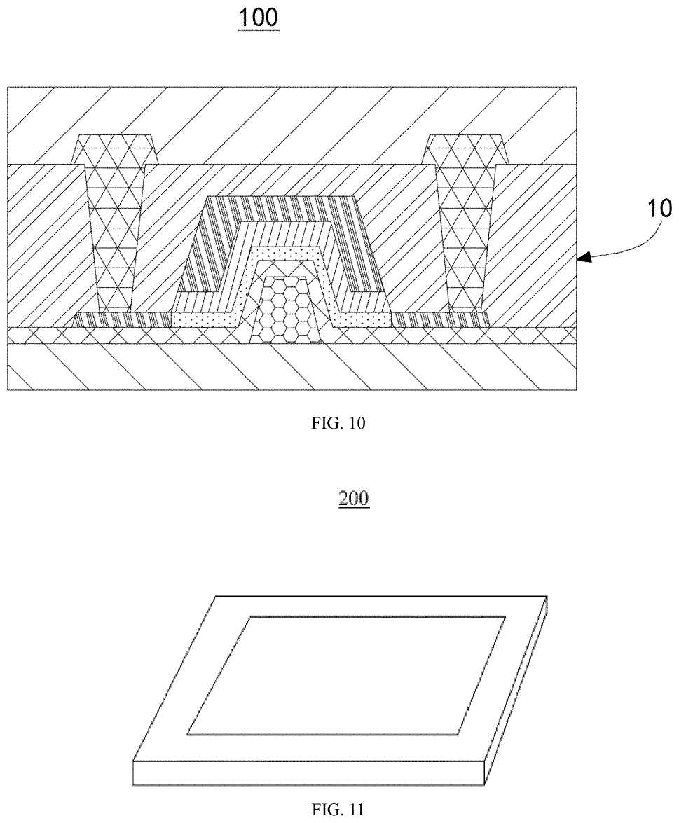

As illustrated in FIG. 10, an array substrate 100 is provided. The array substrate 100 includes the thin film transistor 10 described above.

As illustrated in FIG. 11, a display device 200 is provided. The display device 200 includes the array substrate 100 described above.

The existing oxide transistors (such as, IGZO transistors that have a top gate structure (top-gate IGZO transistors)) have low parasitic capacitances and thus are suitable for development of organic light-emitting diode (OLED) panels with high PPI. However, it is difficulty to design the channel of the IGZO transistor to be shorter than 4 microns since there may be about 1 micron of carrier diffusion length from a conductive region (non-channel region/source-drain region) of the IGZO transistor to a semiconductor region of the IGZO transistor, thereby causing a decrease in the length of the channel. In addition, a shorter channel of the IGZO transistor may lead to more negative shift of the Vth (critical voltage/threshold voltage), which may affect the performance of the IGZO transistor.

In contrast, in the thin film transistor 10, the manufacturing method for a thin film transistor, the array substrate, and the display device that are provided herein, the channel portion 141 protrudes toward the gate electrode 16 to form a curved structure. In other words, by means of that the channel portion is designed to extend vertically, a length of the thin film transistor 10 in the horizontal direction can be reduced in a case that the length of the channel is not changed. Since the length of the channel portion 141 is increased and the length of the thin film transistor 10 in the horizontal direction is not changed, the narrow channel can be realized and PPI can be improved. In addition, since the channel portion 141 is designed as a curved shape, the thin film transistors 10 can be densely distributed in the array substrate, and thus the display performance can be improved. Furthermore, the first buffer layer 12 and the second buffer layer 13 are arranged in layers, and the second buffer layer 13 is formed on the first buffer layer 12, which is conducive to the formation of the oxide semiconductor layer 14 with a good shape, thereby improving the performance of the thin film transistor 10.

The foregoing illustrates some implementations of the disclosure. It can be understood that for those skilled in the art, without departing from the principle of the disclosure, a number of improvements and modifications can be made, which are also regarded as the protection scope of the disclosure.

What is claimed is:

1. A thin film transistor, comprising:
a substrate; and
an oxide semiconductor layer, a gate electrode, a gate insulation layer, a source electrode, and a drain electrode that are disposed on the substrate, wherein the oxide semiconductor layer comprises a channel portion, a first contact portion, and a second contact portion, wherein the source electrode is in contact with the first contact portion, and the drain electrode is in contact with the second contact portion; the channel portion at least partially protrudes in a direction away from the substrate, and the gate insulation layer and the gate electrode are successively stacked on the channel portion.

2. The thin film transistor of claim 1, wherein the channel portion comprises a first part and two second parts respectively located on two opposite ends of the first part, wherein each of the two second parts is bent from one of the two opposite ends of the first part toward the substrate.

3. The thin film transistor of claim 2, wherein the first part is parallel to the substrate, wherein an angle defined between each of the two second parts and the first part is larger than 90 degrees and smaller than 180 degrees.

4. The thin film transistor of claim 3, wherein the channel portion further comprises two third parts, one third part connected between one second part and the first contact portion, the other third part connected between the other second part and the second contact portion.

5. The thin film transistor of claim 4, wherein the two third parts are both parallel to the first part.

6. The thin film transistor of claim 4, wherein the gate insulation layer covers the first part, the two second parts, and the two third parts.

7. The thin film transistor of claim 2, wherein the first part and the two second parts jointly form a protrusion relative to the substrate.

8. The thin film transistor of claim 1, further comprising a buffer layer, wherein the buffer layer is located on and at least partially protrudes relative to the substrate, and the oxide semiconductor layer is arranged on the buffer layer.

9. The thin film transistor of claim 8, wherein the buffer layer comprises a first buffer layer and a second buffer layer covering the first buffer layer, wherein the oxide semiconductor layer is arranged on a surface of the second buffer layer away from the first buffer layer.

10. The thin film transistor of claim 9, wherein the first buffer layer has a first end adjacent to the substrate, and the first end has a width greater than that of a second end opposite to the first end.

11. The thin film transistor of claim 9, wherein the first buffer layer and the second buffer layer are made from a same material, wherein the second buffer layer and the first buffer layer are arranged on the substrate in layers.

12. The thin film transistor of claim 9, wherein an orthographic projection of the first contact portion on the substrate has no overlap with an orthographic projection of the first buffer layer on the substrate.

13. The thin film transistor of claim 9, wherein an orthographic projection of the second contact portion on the substrate has no overlap with an orthographic projection of the first buffer layer on the substrate.

14. The thin film transistor of claim 1, wherein the oxide semiconductor layer is made from materials comprising indium gallium zinc oxide.

15. A display device comprising a thin film transistor, wherein the thin film transistor comprises:
a substrate; and
an oxide semiconductor layer, a gate electrode, a gate insulation layer, a source electrode, and a drain electrode that are disposed on the substrate, wherein the oxide semiconductor layer comprises a channel portion, a first contact portion, and a second contact portion, wherein the source electrode is in contact with the first contact portion, and the drain electrode is in contact with the second contact portion; the channel portion at least partially protrudes in a direction away from the substrate, and the gate insulation layer and the gate electrode are successively stacked on the channel portion.

16. A manufacturing method for a thin film transistor, comprising:
forming, on a substrate, an oxide semiconductor layer, wherein a part of the oxide semiconductor layer forms a protrusion in a direction away from the substrate;
forming, on the oxide semiconductor layer, a gate insulation layer and a gate electrode successively;
performing a conductive treatment on two opposite ends of the oxide semiconductor layer to form a first contact portion and a second contact portion, wherein the oxide semiconductor layer connected between the first contact portion and the second contact portion forms a channel portion, and the channel portion at least partially protrudes in a direction away from the substrate; and
forming, on the oxide semiconductor layer, a source electrode and a drain electrode, wherein the source electrode is in contact with the first contact portion and the drain electrode is in contact with the second contact portion.

17. The manufacturing method of claim 16, further comprising:
prior to forming, on the substrate, the oxide semiconductor layer,
forming, on the substrate, a buffer layer, wherein the buffer layer at least partially protrudes relative to the substrate.

18. The manufacturing method of claim 17, wherein forming, on the substrate, the oxide semiconductor layer comprises:
forming, on the buffer layer, the oxide semiconductor layer, wherein a part of the oxide semiconductor layer corresponding to a protrusion of the buffer layer protrudes in a direction away from the substrate.

19. The manufacturing method of claim 18, wherein
forming, on the substrate, the buffer layer comprises:
forming, on the substrate, a protruded first buffer layer; and
forming, on the protruded first buffer layer and the substrate, a second buffer layer, wherein at least a part of the channel portion, the second buffer layer, and the protruded first buffer layer are stacked together; and
forming the oxide semiconductor layer on the buffer layer comprises:
forming, on a surface of the second buffer layer away from the protruded first buffer layer, the oxide semiconductor layer.

20. The manufacturing method of claim 16, wherein forming, on the oxide semiconductor layer, the source electrode and the drain electrode comprises:
forming, on the oxide semiconductor layer and the gate electrode, a planarization layer; and
forming, on the planarization layer, the source electrode and the drain electrode.
